(19) United States
(12) Patent Application Publication
(10) Pub. No.: US 2019/0044503 A1
(43) Pub. Date: Feb. 7, 2019

(54) VOLTAGE GENERATOR AND DISPLAY DEVICE HAVING THE SAME

(71) Applicant: Samsung Display Co., Ltd., Yongin-Si (KR)

(72) Inventor: Dongbeom CHO, Seoul (KR)

(21) Appl. No.: 16/050,327

(22) Filed: Jul. 31, 2018

(30) Foreign Application Priority Data
Aug. 2, 2017 (KR) 10-2017-0098242

(51) Int. Cl. H03K 5/133; H03K 5/135; H03K 5/131; G09G 3/36

(52) U.S. Cl. CPC H03K 5/133; G09G 3/3688; H03K 5/131; H03K 5/135

(57) ABSTRACT

A voltage generator of a display device includes a control logic circuit which receives a vertical start signal and a gate pulse signal and outputs a reference pulse signal and delay selection signals, a first clock delay circuit which delays the reference pulse signal during a first time period in response to a first delay selection signal among the delay selection signals to output a first clock signal, and a second clock delay circuit which delays the reference pulse signal during a second time period, which is different from the first time period, in response to a second delay selection signal among the delay selection signals to output a second clock signal.

This application claims priority to Korean Patent Application No. 10-2017-0098242, filed on Aug. 2, 2017, and all the benefits accruing therefrom under 35 U.S.C. § 119, the content of which in its entirety is herein incorporated by reference.

### BACKGROUND

### 1. Field

The disclosure relates to a voltage generator that generates a clock signal and voltages and a display device including the voltage generator.

### 2. Description of the Related Art

In general, a display device includes a display panel for displaying an image and a driving circuit for driving the display panel. The display panel typically includes gate lines, data lines, and pixels. Each of the pixels is connected to a corresponding gate line among the gate lines and a corresponding data line among the data lines. The driving circuit typically includes a source driver for applying a data signal to the data lines, a gate driver for outputting gate signals to drive the gate lines, a voltage generator for applying clock signals to the gate driver, and a timing controller for controlling the data driver and the gate driver.

The voltage generator may generate the clock signals in response to a gate pulse signal provided from the timing controller. When the number of the clock signals for the gate driver increases, the number of the gate pulse signals provided to the voltage generator from the timing controller may increase.

### SUMMARY

The disclosure relates to a voltage generator capable of reducing the number of gate pulse signals provided thereto from a timing controller.

The disclosure relates to a display device including the voltage generator.

According to an embodiment of the invention, a voltage generator includes a control logic circuit which receives a vertical start signal and a gate pulse signal and outputs a reference pulse signal and delay selection signals, a first clock delay circuit which delays the reference pulse signal during a first time period in response to a first delay selection signal among the delay selection signals to output a first clock signal, and a second clock delay circuit which delays the reference pulse signal during a second time period, which is different from the first time period, in response to a second delay selection signal among the delay selection signals to output a second clock signal.

In an embodiment, the first clock delay circuit may delay the reference pulse signal during a third time period in response to a third delay selection signal among the delay selection signals to output a third clock signal, and the second clock delay circuit may delay the reference pulse signal during a fourth time period in response to a fourth delay selection signal among the delay selection signals to output a fourth clock signal, where the first to fourth time periods are in one period of the reference pulse signal and different from each other. In such an embodiment, the first clock signal and the third clock signal may be substantially complementary to each other, and the second clock signal and the fourth clock signal may be substantially complementary to each other.

In an embodiment, the control logic circuit may generate a gate-on voltage and a gate-off voltage. The first clock delay circuit may output the first and third clock signals, each of which is swinging between the gate-on voltage and the gate-off voltage, and the second clock delay circuit may output the second and fourth clock signals, each of which is swinging between the gate-on voltage and the gate-off voltage.

In an embodiment, the first clock delay circuit may include a first delay circuit which outputs one delay pulse signal by delaying the reference pulse signal during the first time period in response to the first delay selection signal, a first output circuit which converts the first delay pulse signal to the first clock signal swinging between the gate-on voltage and the gate-off voltage and outputs the first clock signal, a third delay circuit which outputs another delay pulse signal by delaying the reference pulse signal during a third time period in response to the third delay selection signal, and a third output circuit which converts the third delay pulse signal to the third clock signal swinging between the gate-on voltage and the gate-off voltage and outputs the third clock signal.

In an embodiment, the control logic circuit may further generate a first charge share signal and a second charge share signal in response to the gate pulse signal. In such an embodiment, the first clock delay circuit may further include a charge share circuit which electrically connects one signal line, through which the first clock signal is transmitted, to another signal line, through which the third clock signal is transmitted, in response to the first charge share signal.

In an embodiment, the control logic circuit may further generate charge share delay signals, and the first clock delay circuit may include one charge share delay circuit which outputs one delayed charge share signal by delaying the first charge share signal during a predetermined time period in response to one charge share delay signal among the charge share delay signals, and another charge share delay circuit which outputs another delayed charge share signal by delaying the first charge share signal during a predetermined time period in response to another charge share delay signal among the charge share delay.

In an embodiment, the one delay circuit may delay the reference pulse signal in response to the first delay selection signal and the one delayed charge share signal to output the one delay pulse signal, and the third delay circuit may delay the reference pulse signal in response to the third delay selection signal and the another delayed charge share signal to output the another delay pulse signal.

In an embodiment, the first clock delay circuit may include one output circuit which converts the reference pulse signal to one boosting clock signal swinging between the gate-on voltage and the gate-off voltage and outputs the one boosting clock signal, a first delay circuit which delays the one boosting clock signal during the first time period in response to the first delay selection signal to output the first clock signal, a third output circuit which converts the reference pulse signal to another boosting clock signal swinging between the gate-on voltage and the gate-off voltage and outputs the another boosting clock signal, and a third delay circuit which delays the another boosting clock signal during the third time period in response to the third delay selection signal to output the another clock signal.

In an embodiment, the control logic circuit may further generate a first charge share signal and a second charge share signal in response to the gate pulse signal, and the first clock delay circuit may further include a charge share circuit which electrically connects one signal line, through which the first clock signal is transmitted, to another line, through which the third clock signal is transmitted, in response to the first charge share signal.

In an embodiment, the control logic circuit may further generate charge share delay signals. In such an embodiment, the first clock delay circuit may include one charge share delay circuit which outputs one delayed charge share signal by delaying the first charge share signal during a predetermined time period in response to one charge share delay signal among the charge share delay signals, and another charge share delay circuit which outputs another delayed charge share signal by delaying the first charge share signal during a predetermined time period in response to another charge share delay signal among the charge share delay signals.

In an embodiment, the one delay circuit may delay the one boosting clock signal in response to the first delay selection signal and the one delayed charge share signal to output the first clock signal, and the third delay circuit may delay the another boosting clock signal in response to the third delay selection signal and the another delayed charge share signal to output the third clock signal.

In an embodiment, the first, second, third and fourth clock signals may have different phases from each other within one period of the reference pulse signal.

According to another embodiment of the invention, a display device including a display panel includes a plurality of gate lines, a plurality of data lines, and a plurality of pixels connected to the gate lines and the data lines, a gate driver which drives the gate lines, a data driver which drives the data lines, a timing controller which outputs a vertical start signal and a gate pulse signal based on a control signal and an image signal from an outside thereof to control the gate driver and the data driver, and a voltage generator which receives the vertical start signal and the gate pulse signal from the timing controller and outputs a driving voltage, a first clock signal and a second clock signal. In such an embodiment, the voltage generator includes a control logic circuit which receives the vertical start signal and the gate pulse signal and outputs a reference pulse signal and delay selection signals, a first clock delay circuit which delays the reference pulse signal during a first time period in response to a first delay selection signal among the delay selection signals to output the first clock signal, and a second clock delay circuit which delays the reference pulse signal during a second time period, which is different from the first time period, in response to a second delay selection signal among the delay selection signals to output the second clock signal.

In an embodiment, the first clock delay circuit may delay the reference pulse signal during a third time period in response to a third delay selection signal among the delay selection signals to output a third clock signal, and the second clock delay circuit may delay the reference pulse signal during a fourth time period in response to a fourth delay selection signal among the delay selection signals to output a fourth clock signal. In such an embodiment, the first clock signal and the third clock signal may be substantially complementary to each other, and the second clock signal, and the fourth clock signal may be substantially complementary to each other.

In an embodiment, the control logic circuit may generate a gate-on voltage and a gate-off voltage. In such an embodiment, the first clock delay circuit may output the first and third clock signals, each of which is swinging between the gate-on voltage and the gate-off voltage, and the second clock delay circuit outputs the second and fourth clock signals, each of which is swinging between the gate-on voltage and the gate-off voltage.

According to another embodiment of the invention, a display device includes a display panel including a plurality of gate lines, a plurality of data lines, and a plurality of pixels connected to the gate lines and the data lines, a gate driver which drives the gate lines, a data driver which drives the data lines, a timing controller which outputs a vertical start signal and a gate pulse signal based on a control signal and an image signal from an outside thereof to control the gate driver and the data driver, and a voltage generator which receives the vertical start signal and the gate pulse signal and outputs a driving voltage, a switching signal, a first output clock signal and a second output clock signal. In such an embodiment, the voltage generator includes a control logic circuit which receives the vertical start signal and the gate pulse signal to output a reference pulse signal, the switching signal, and first, second, third and fourth delay selection signals, and a clock delay circuit sequentially outputs the first output clock signal and sequentially outputs the second output clock signal, where the first output clock signal is generated by delaying the reference pulse signal during a first time period and generated by delaying the reference pulse signal during a second time period in response to the first and second delay selection signals, and the second output clock signal is generated by delaying the reference pulse signal during a third time period and generated by delaying the reference pulse signal during a fourth time period in response to the third and fourth delay selection signals. In such an embodiment, the gate driver drives the gate lines based on the switching signal, the first output clock signal and the second output clock signal.

In an embodiment, the gate driver may further include a switching circuit which sequentially outputs the first output clock signal as first and second clock signals in response to the switching signal and sequentially outputs the second output clock signal as third and fourth clock signals in response to the switching signal, and a plurality of stages which drives the gate lines in synchronization with the first, second, third and fourth clock signals.

In an embodiment, the switching circuit may include a first switching unit which outputs the first output clock signal as the first clock signal in response to the switching signal, a second switching unit which outputs the first output clock signal as the second clock signal in response to the switching signal, a third switching unit which outputs the second output clock signal as the third clock signal in response to the switching signal, and a fourth switching unit outputting the second output clock signal as the fourth clock signal in response to the switching signal.

In an embodiment, the control logic circuit may generate a gate-on voltage and a gate-off voltage, and the clock delay circuit may include a first delay circuit which sequentially outputs a first delayed pulse signal, where the first delayed pulse signal is generated by delaying the reference pulse signal during the first time period and generated by delaying the reference pulse signal during the second time period in response to the first and second delay selection signals, a first output circuit which converts the first delayed pulse signal to the first output clock signal swinging between the gate-on voltage and the gate-off voltage and outputs the first output clock signal, a second delay circuit which sequentially outputs a second delayed pulse signal, wherein the second delayed pulse signal is generated by delaying the reference pulse signal during the third time period and generated by delaying the reference pulse signal during the fourth time period in response to the third and fourth delay selection signals, and a second output circuit which converts the second delayed pulse signal to the second output clock signal swinging between the gate-on voltage and the gate-off voltage and outputs the second output clock signal.

In an embodiment, the control logic circuit may further generate a charge share signal in response to the gate pulse signal, and the clock delay circuit may further include a charge share circuit which electrically connects one signal line, through which the first output clock signal is transmitted, and another signal line, through which the second output clock signal is transmitted, in response to the charge share signal.

According to embodiments as set forth herein, the voltage generator may generate the clock signals using one gate pulse signal provided from the timing controller. Although the number of the clock signals used by the gate driver increases, the number of the gate pulse signals provided to the voltage generator from the timing controller does not increase. Accordingly, the number of the output terminals of the timing controller and the number of the input terminals of the voltage generator may be reduced.

### BRIEF DESCRIPTION OF THE DRAWINGS

The above and other features of the invention will become readily apparent by reference to the following detailed description when considered in conjunction with the accompanying drawings, in which:

FIG. 1 is a block diagram showing a display device according to an exemplary embodiment of the disclosure;

FIG. 2 is a block diagram showing a gate driver according to an exemplary embodiment of the disclosure;

FIG. 3 is a block diagram showing a voltage generator according to an exemplary embodiment of the disclosure;

FIG. 4 is a signal timing diagram showing an operation of a voltage generator according to an exemplary embodiment of the disclosure;

FIG. 5 is a circuit diagram showing an exemplary embodiment of a first clock delay circuit shown in FIG. 4;

FIG. 6 is a block diagram showing a voltage generator according to an alternative exemplary embodiment of the disclosure;

FIG. 7 is a circuit diagram showing an exemplary embodiment of a first clock delay circuit shown in FIG. 6;

FIG. 8 is a signal timing diagram showing an operation of a voltage generator according to another alternative exemplary embodiment of the disclosure;

FIG. 9 a block diagram showing a voltage generator according to another alternative exemplary embodiment of the disclosure;

FIG. 10 is a circuit diagram showing an exemplary embodiment of a delay circuit of a first clock delay circuit shown in FIG. 9;

FIG. 11 is a block diagram showing a voltage generator according to another alternative exemplary embodiment of the disclosure;

FIG. 12 is a circuit diagram showing an exemplary embodiment of a delay circuit of a first clock delay circuit shown in FIG. 11;

FIG. 13 is a block diagram showing a display device according to an alternative exemplary embodiment of the disclosure;

FIG. 14 is a block diagram showing an exemplary embodiment of a gate driver shown in FIG. 13; and

FIG. 15 is a block diagram showing an exemplary embodiment of a voltage generator shown in FIG. 13.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Hereinafter, exemplary embodiments of the invention will be described in detail with reference to the accompanying drawings.

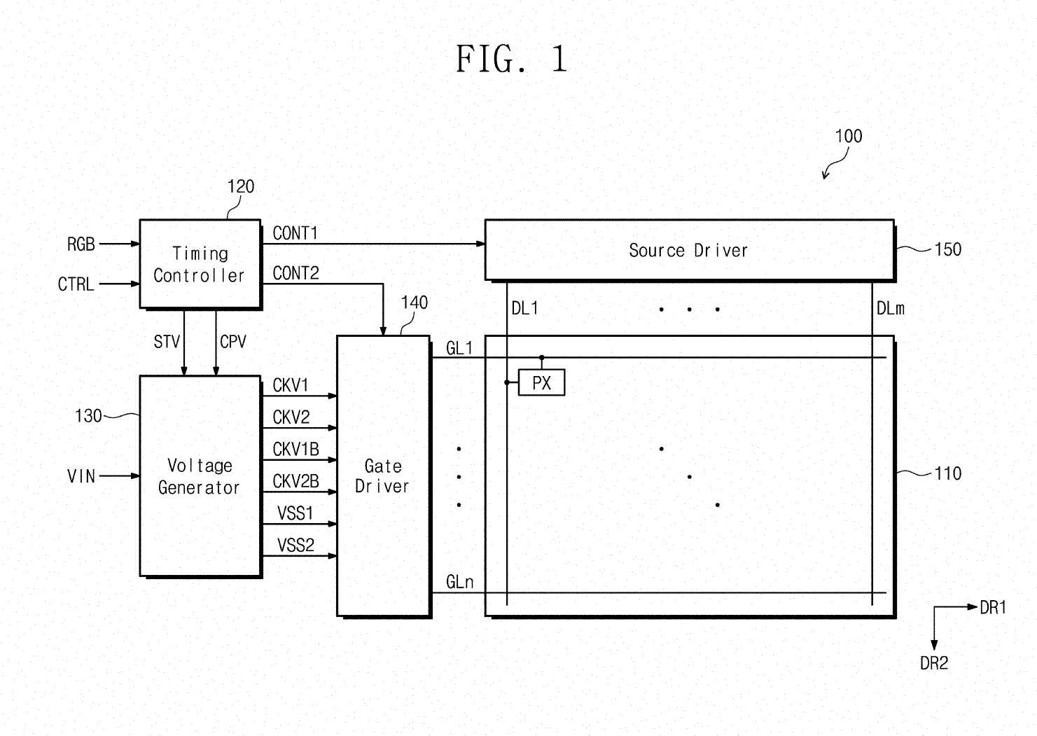

FIG. 1 is a block diagram showing a display device 100 according to an exemplary embodiment of the disclosure.

Referring to FIG. 1, an exemplary embodiment of the display device 100 includes a display panel 110, a timing controller 120, a voltage generator 130, a gate driver 140, and a source driver 150.

The display panel 110 may be, but not limited to, a liquid crystal display panel, an organic light emitting display panel, an electrophoretic display panel, or an electrowetting display panel. In an exemplary embodiment, where the display panel 110 is the liquid crystal display panel, the display panel 110 may further include a polarizer and a backlight unit.

The display panel 110 includes a plurality of pixels PX, a plurality of gate lines GL1 to GLn extending in a first direction DR1, and a plurality of data lines DL1 to DLm in a second direction DR2 crossing the first direction DR1. The gate lines GL1 to GLn are connected to the gate driver 140. The data lines DL1 to DLm are connected to the source driver 150. For convenience of illustration, FIG. 1 shows some of the gate lines GL1 to GLn and some of the data lines DL1 to DLm.

For convenience of illustration, FIG. 1 shows only one pixel PX among the pixels. Each of the pixels PX is connected to a corresponding gate line among the gate lines GL1 to GLn and a corresponding data line among the data lines DL1 to DLm.

The timing controller 120 receives image data RGB and control signals CTRL from an external graphic controller (not shown). The control signals CTRL include a vertical synchronization signal as a frame distinction signal, a signal to distinct horizontal periods, i.e., a horizontal synchronization signal as a row distinction signal, a data enable signal maintained at a high level during a period, in which data are output, to indicate a data input period, and clock signals.

The timing controller 120 receives the image data RGB and the control signals CTRL, outputs a data signal and a source control signal CONT1 to the source driver 150, outputs a gate control signal CONT2 to the gate driver 140, and outputs a start signal STV and a gate pulse signal CPV to the voltage generator 130.

The voltage generator 130 receives the start signal STV and the gate pulse signal CPV from the timing controller 120, and generates first, second, third, and fourth clock signals CKV1, CKV2, CKV1B and CKV2B based on the start signal STV and the gate pulse signal CPV. Hereinafter, for convenience of description, exemplary embodiments, where the voltage generator 130 receives a single gate pulse signal CPV and outputs four clock signals CKV1, CKV2, CKV1B and CKV2B, will be described in detail, but not being limited thereto. In exemplary embodiments of the invention, the number of the clock signals may be variously modified based on the configuration of the gate driver 140. The voltage generator 130 may receive an input voltage VIN from an external source.

The voltage generator 130 may be implemented by a power management integrated circuit (“PMIC”). The voltage generator 130 may further generate a common voltage, a power source voltage and a ground voltage, which are used to drive the display panel 110, and a first voltage VSS1 and a second voltage VSS2, which are used to drive the gate driver 140, in addition to the first, second, third and fourth clock signals CKV1, CKV2, CKV1B and CKV2B.

The gate driver 140 generates gate signals based on the gate control signal CONT2 provided from the timing controller 130 during frame periods and the first, second, third and fourth clock signals CKV1, CKV2, CKV1B and CKV2B, and outputs the gate signals to the gate lines GL1 to GLn. In an exemplary embodiment, the gate driver 140 may be substantially simultaneously provided or formed with the pixels PX through a thin film process. In one exemplary embodiment, for example, the gate driver 140 may be mounted in a predetermined area (e.g., a non-display area in which the pixels PX are not arranged) in an oxide semiconductor thin film transistor (“TFT”) gate driver circuit (“OSG”). In an alternative exemplary embodiment, the gate driver 140 may include a driving chip (not shown) and a flexible printed circuit board (not shown) on which the driving chip is mounted. In another alternative exemplary embodiment, the gate driver 140 may be mounted in the non-display area of the display panel 110 in a chip-on-glass (“COG”) method.

The source driver 150 generates grayscale voltages corresponding to the image data provided from the timing controller 120 in response to the source control signal CONT1 from the timing controller 120.

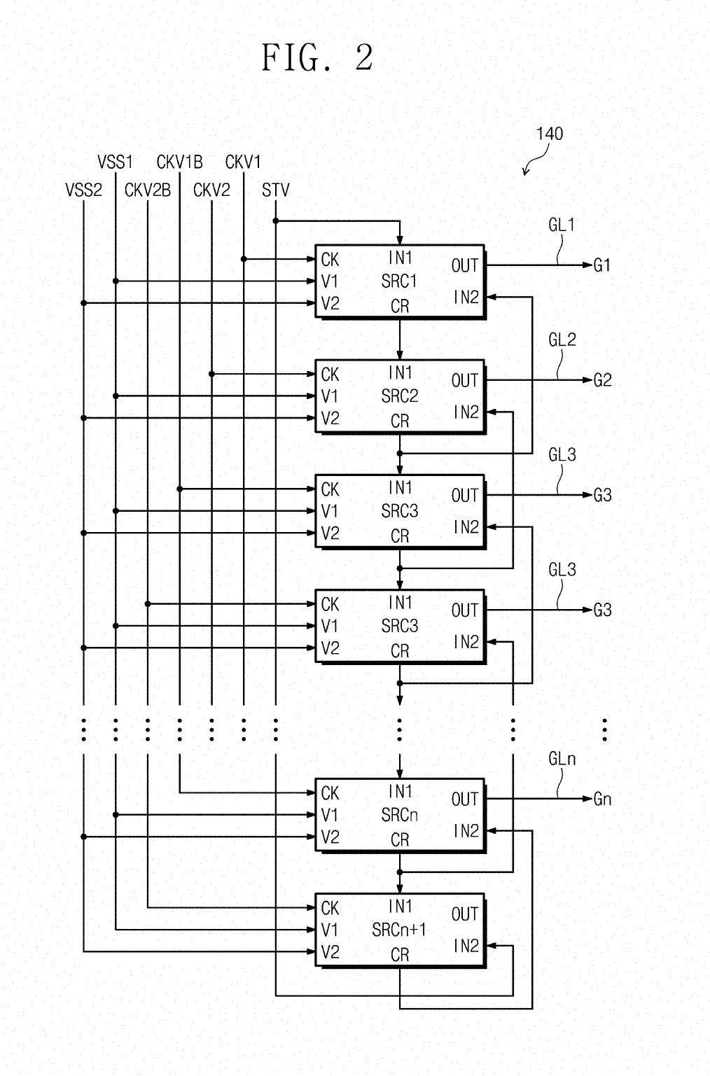

FIG. 2 is a block diagram showing an exemplary embodiment of the gate driver 140.

Referring to FIG. 2, an exemplary embodiment of the gate driver 140 includes a plurality of driving stages SRC1 to SRCn and a dummy driving stage SRCn+1. The driving stages SRC1 to SRCn and the dummy driving stage SRCn+1 are connected to each other in a cascade manner to allow each driving stage to be driven in response to a carry signal output from a previous driving stage and/or a carry signal output from a next driving stage.

Each of the driving stages SRC1 to SRCn and the dummy driving stage SRCn+1 receives one of the four clock signals, i.e., a first clock signal CKV1, a second clock signal CKV2, a third clock signal CKV1B and a fourth clock signal CKV2B, provided from the voltage generator 130 (shown in FIG. 1). The first driving stage SRC1 and the dummy driving stage SRCn+1 further receive the start signal STV.

In an exemplary embodiment, as shown in FIG. 2, the gate driver 140 receives four clock signals, e.g., the first, second, third, and fourth clock signals CKV1, CKV2, CKV1B and CKV2B, but not being limited thereto. Alternatively, the gate driver 140 may receive two clock signals, eight clock signals, twelve clock signals or sixteen clock signals depending on a circuit configuration of the driving stages SRC1 to SRCn and the dummy driving stage SRCn+1 of the gate driver 140.

In an exemplary embodiment, the driving stages SRC1 to SRCn are connected to the gate lines GL1 to GLn, respectively. The driving stages SRC1 to SRCn apply the gate signals G1 to Gn to the gate lines GL1 to GLn, respectively. In an exemplary embodiment, the gate lines connected to the driving stages SRC1 to SRCn may be odd-numbered gate lines or even-numbered gate lines among the gate lines GL1 to GLn.

Each of the driving stages SRC1 to SRCn and the dummy driving stage SRCn+1 includes a first input terminal IN1, a second input terminal IN2, a gate output terminal OUT, a carry output terminal CR, a clock terminal CK, a first power terminal V1 and a second power terminal V2.

The gate output terminal OUT of each of the driving stages SRC1 to SRCn is connected to a corresponding gate line of the gate lines GL1 to GLn. The gate signals G1 to Gn generated by the driving stages SRC1 to SRCn are applied to the gate lines GL1 to GLn, respectively, through the gate output terminals OUT thereof.

In an exemplary embodiment, as shown in FIG. 2, the carry output terminal CR of each of the driving stages SRC1 to SRCn is electrically connected to the first input terminal IN1 of a next driving stage thereof. In such an embodiment, the carry output terminal CR of each of the driving stages SRC2 to SRCn is electrically connected to the second input terminal IN2 of the previous driving stage thereof. In one exemplary embodiment, for example, the carry output terminal CR of a k-th driving stage SRCk of the driving stages SRC1 to SRCn is connected to the second input terminal IN2 of a (k−1)-th driving stage SRCk−1 and the first input terminal IN1 of a (k+1)-th driving stage SRCk+1. Here, k is a natural number less than or equal to n. The carry output terminal CR of each of the driving stages SRC1 to SRCn and the dummy driving stage SRCn+1 outputs the carry signal.

The first input terminal IN1 of each of the driving stages SRC2 to SRCn and the dummy driving stage SRCn+1 receives the carry signal from the previous driving stage thereof. In one exemplary embodiment, for example, the first input terminal IN1 of the k-th driving stage SRCk receives the carry signal CRk−1 output from the (k−1)-th driving stage SRCk−1. Among the driving stages SRC1 to SRCn, the first input terminal IN1 of the first driving stage SRC1 receives the start signal STV included in the gate control signal CONT2 provided from the timing controller 120 (shown in FIG. 1) instead of the carry signal of the previous driving stage.

The second input terminal IN2 of each of the driving stages SRC1 to SRCn receives the carry signal from the carry output terminal CR of the next driving stage thereof. In one exemplary embodiment, for example, the second input terminal IN2 of the k-th driving stage SRCk receives the carry signal CRk+1 output from the carry output terminal CR of the (k+1)-th driving stage SRCk+1. According to an alternative exemplary embodiment, the second input terminal IN2 of each of the driving stages SRC1 to SRCn may be electrically connected to the gate output terminal OUT of the next driving stage thereof. The second input terminal IN2 of the driving stage SRCn receives the carry signal CRn+1 output from the carry output terminal CR of the dummy driving stage SRCn+1.

The clock terminal CK of each of the driving stages SRC1 to SRCn receives one of the first, second, third and fourth clock signals CKV1, CKV2, CKV1B, and CKV2B. In one exemplary embodiment, for example, the clock terminal CK of driving stage SRC1 receives the first clock signal CKV1. The clock terminal CK of driving stage SRC2 receives the second clock signal CKV2. The clock terminal CK of driving stage SRC3 receives the third clock signal CKV1B. The clock terminal CK of driving stage SRC4 receives the fourth clock signal CKV2B. The first, second, third and fourth clock signals CKV1, CKV2, CKV1B and CKV2B have different phases from each other.

The first power terminal V1 of each of the driving stages SRC1 to SRCn receives the first voltage VSS1, and the second power terminal V2 of each of the driving stages SRC1 to SRCn receives the second voltage VSS2. The first and second voltages VSS1 and VSS2 have different voltage levels from each other, and the second voltage VSS2 may have a voltage level lower than that of the first voltage VSS1.

In an exemplary embodiment, one of the first input terminal IN1, the second input terminal IN2, the gate output terminal OUT, the carry output terminal CR, the clock terminal CK, the first power terminal V1 and the second power terminal V2 may be omitted from each of the driving stages SRC1 to SRCn, or another terminal may be further added to each of the driving stages SRC1 to SRCn. In one exemplary embodiment, for instance, one of the first and second power terminals V1 and V2 may be omitted. In such an embodiment, each of the driving stages SRC1 to SRCn receives only one of the first voltage VSS1 and the second voltage VSS2. In such an embodiment, a connection relation between the driving stages SRC1 to SRCn may be changed.

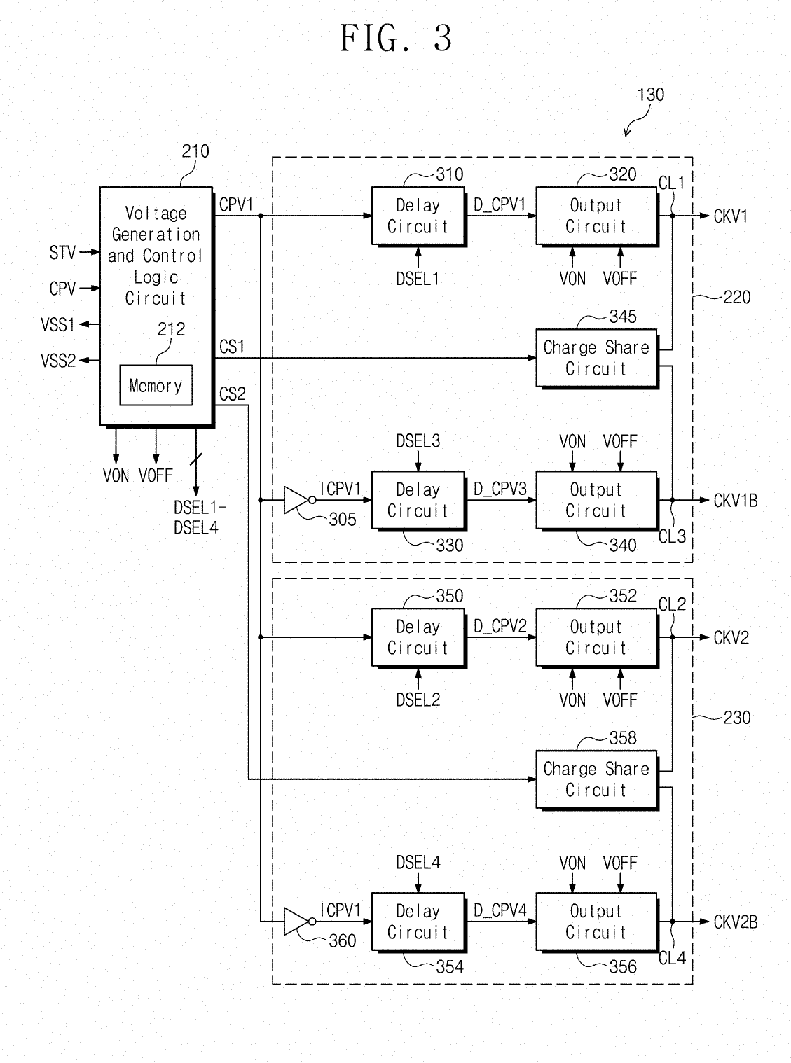

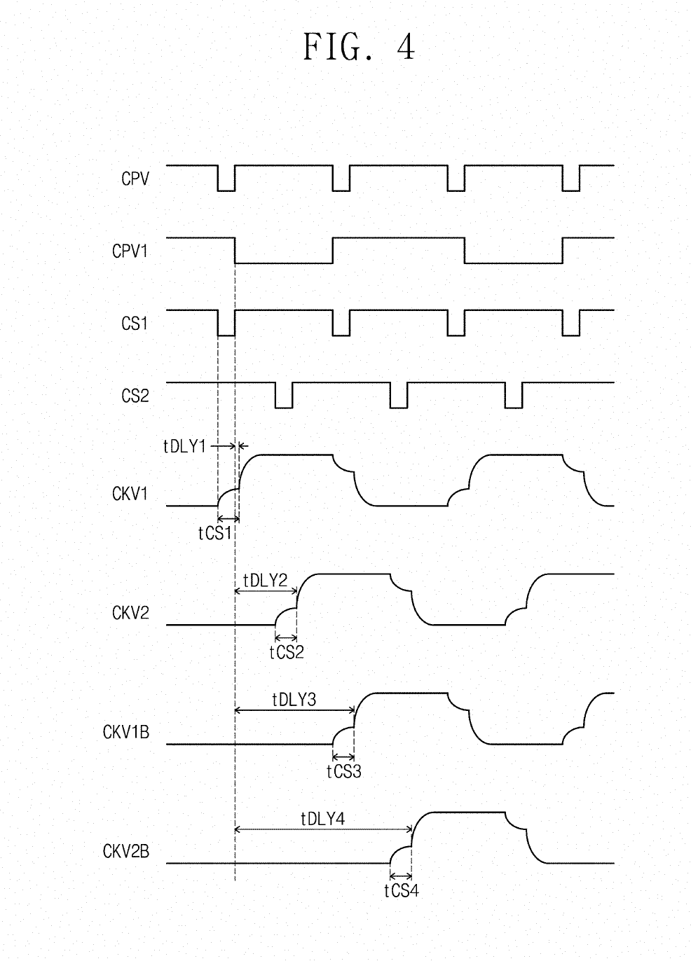

FIG. 3 is a block diagram showing the voltage generator 130 according to an exemplary embodiment of the disclosure. FIG. 4 is a signal timing diagram showing an operation of the voltage generator 130 according to an exemplary embodiment of the disclosure.

Referring to FIG. 3, an exemplary embodiment of the voltage generator 130 includes a voltage generation and control logic circuit 210, a first clock delay circuit 220, and a second clock delay circuit 230. The voltage generation and control logic circuit 210 receives the start signal STV and the gate pulse signal CPV from the timing controller 120 (shown in FIG. 1). The voltage generation and control logic circuit 210 generates the first voltage VSS1, the second voltage VSS2, a gate-on voltage VON and a gate-off voltage VOFF. The voltage generation and control logic circuit 210 may further generate voltages, such as the common voltage, the power source voltage, etc., for the operation of the display device 100. The voltage generation and control logic circuit 210 outputs a reference pulse signal CPV1, first and second charge share signals CS1 and CS2, and first, second, third and fourth delay selection signals DSEL1, DSEL2, DSEL3 and DSEL4 based on the start signal STV and the gate pulse signal CPV.

The first clock delay circuit 220 delays the reference pulse signal CPV1 during a first delay time (i.e., time period or duration) tDLY1 in response to the first delay selection signal DSEL1 from the voltage generation and control logic circuit 210 to output the first clock signal CKV1. The first clock delay circuit 220 delays the reference pulse signal CPV1 during a third delay time period tDLY3 in response to the third delay selection signal DSEL3 from the voltage generation and control logic circuit 210 to output the third clock signal CKV1B.

The first clock delay circuit 220 includes first and third delay circuits 310 and 330, first and third output circuits 320 and 340, a charge share circuit 345, and an inverter 305.

The first delay circuit 310 delays the reference pulse signal CPV1 during the first delay time tDLY1 in response to the first delay selection signal DSEL1 to output the first delay pulse signal D_CPV1. The first output circuit 320 converts the first delay pulse signal D_CPV1 to the first clock signal CKV1 swinging between the gate-on voltage VON and the gate-off voltage VOFF, and outputs the first clock signal CKV1.

The inverter 305 outputs an inversion reference pulse signal ICPV1 generated by inverting the reference pulse signal CPV1. The third delay circuit 330 delays the inversion reference pulse signal ICPV1 during the third delay time tDLY3 in response to the third delay selection signal DSEL3 to output the third delay pulse signal D_CPV3. The third output circuit 340 converts the third delay pulse signal D_CPV3 to the third clock signal CKV1B swinging between the gate-on voltage VON and the gate-off voltage VOFF, and outputs the third clock signal CKV1B.

In response to the first charge share signal CS1, the charge share circuit 345 electrically connects a first signal line CL1, through which the first clock signal CKV1 is transmitted, and a third signal line CL3, through which the third clock signal CKV1B is transmitted.

The second clock delay circuit 230 delays the reference pulse signal CPV1 during a second delay time tDLY2 in response to the second delay selection signal DSEL2 from the voltage generation and control logic circuit 210 to output the second clock signal CKV2. The second clock delay circuit 230 delays the reference pulse signal CPV1 during a fourth delay time tDLY4 in response to the fourth delay selection signal DSEL4 from the voltage generation and control logic circuit 210 to output the fourth clock signal CKV2B.

The second clock delay circuit 230 includes second and fourth delay circuits 350 and 354, second and fourth output circuits 352 and 356, a charge share circuit 358, and an inverter 360.

The second and fourth delay circuits 350 and 354, the second and fourth output circuits 352 and 356, the charge share circuit 358 and the inverter 360 of the second clock delay circuit 230 are substantially the same as the first and third delay circuits 310 and 330, the first and third output circuits 320 and 340, the charge share circuit 345 and the inverter 305 of the first clock delay circuit 220, except that the charge share circuit 358 receives the second charge share signal CS2 and electrically connects a second signal line CL2, through which the second clock signal CKV1 is transmitted, and a fourth signal line CL4, through which the fourth clock signal CKV1B is transmitted. Accordingly, any repetitive detailed description thereof will be omitted.

The voltage generation and control logic circuit 210 may include a memory 212. The memory 212 may store information about the first to fourth delay times tDLY1 to tDLY4 of the first to fourth delay circuits 310, 330, 350, and 354. The voltage generation and control logic circuit 210 may output the first to fourth delay selection signals DSEL1 to DSEL4 based on the information about the first to fourth delay times tDLY1 to tDLY4 stored in the memory 212.

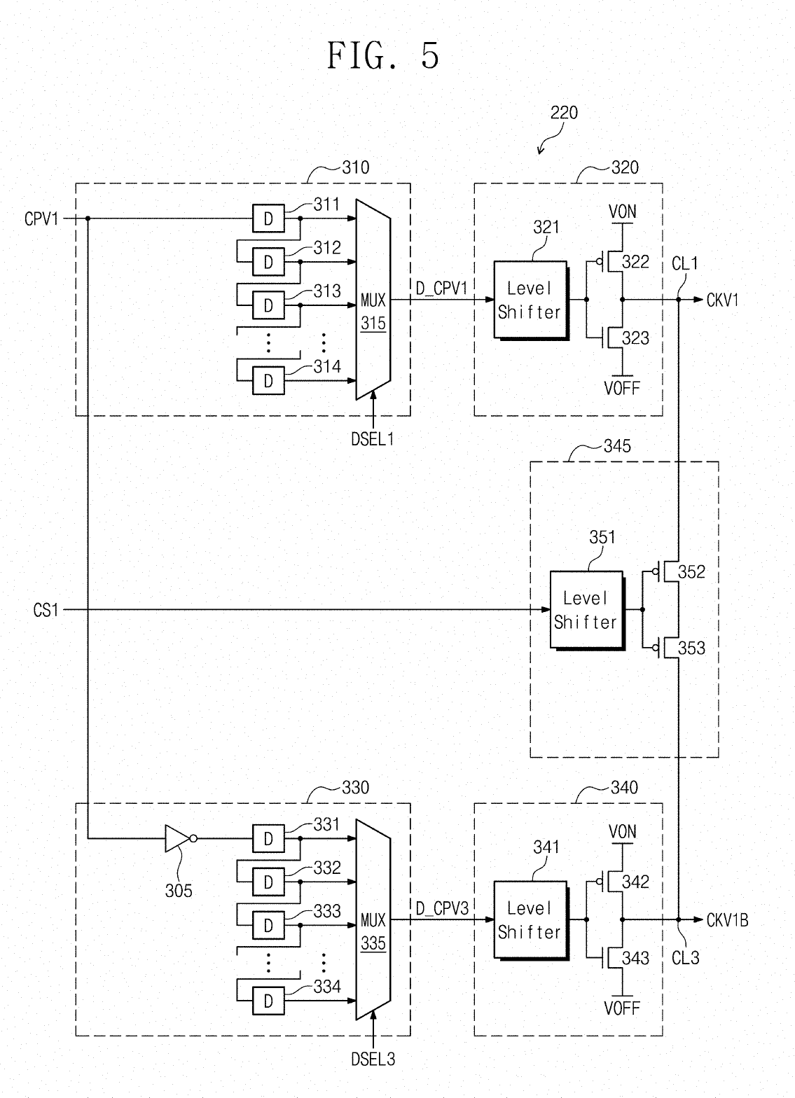

FIG. 5 is a circuit diagram showing an exemplary embodiment of the first clock delay circuit 220 shown in FIG. 4.

Referring to FIGS. 4 and 5, an exemplary embodiment of the first delay circuit 310 of the first clock delay circuit 220 includes a plurality of delay units 311 to 314 and a multiplexer 315. A first delay unit 311 of the delay units 311 to 314 receives the reference pulse signal CPV1. The delay units 311 to 314 are connected to each other in series. The multiplexer 315 receives output signals from the delay units 311 to 314, and outputs a signal output from one of the delay units 311 to 314 as the first delay pulse signal D_CPV1, in response to the first delay selection signal DSEL1. Each of the delay units 311 to 314 may include a plurality of inverters connected to each other in series. According to an exemplary embodiment, each of the delay units 311 to 314 may include a buffer circuit. According to an alternative embodiment, each of the delay units 311 to 314 may include a resistance-capacitance (“RC”) delay circuit including a resistor and a capacitor.

The first output circuit 320 includes a level shifter 321, a p-type metal-oxide-semiconductor (“PMOS”) transistor 322, and an n-type metal-oxide-semiconductor (“NMOS”) transistor 323. The first output circuit 320 outputs the gate-on voltage VON as the first clock signal CKV1 when the first delay pulse signal D_CPV1 is at a low level, and outputs the gate-off voltage VOFF as the first clock signal CKV1 when the first delay pulse signal D_CPV1 is at a high level. Therefore, the first clock signal CKV1 swings between the gate-on voltage VON and the gate-off voltage VOFF and has a delayed phase by delaying the reference pulse signal CPV1 by the first delay time tDLY1.

The third delay circuit 330 of the first clock delay circuit 220 includes a plurality of delay units 331 to 334 and a multiplexer 335. A first delay unit 331 receives the reference pulse signal CPV1. The delay units 331 to 334 are connected to each other in series. The multiplexer 335 receives output signals from the delay units 331 to 334, and outputs a signal output from one of the delay units 331 to 334 as the third delay pulse signal D_CPV3, in response to the third delay selection signal DSEL3.

The third output circuit 340 includes a level shifter 341, a PMOS transistor 342, and an NMOS transistor 343. The third output circuit 340 outputs the gate-on voltage VON as the third clock signal CKV1B when the third delay pulse signal D_CPV3 is at a low level and outputs the gate-off voltage VOFF as the third clock signal CKV1B when the third delay pulse signal D_CPV3 is at a high level. Therefore, the third clock signal CKV1B swings between the gate-on voltage VON and the gate-off voltage VOFF and has a delayed phase by delaying the reference pulse signal CPV1 by the third delay time tDLY3.

The charge share circuit 345 includes a level shifter 351 and PMOS transistors 352 and 353. The charge share circuit 345 electrically connects the first signal line CL1, through which the first clock signal CKV1 is transmitted, and the third signal line CL3, through which the third clock signal CKV1B is transmitted.

In an exemplary embodiment, the second clock delay circuit 230 may have substantially the same configuration as that of the first clock delay circuit 220 shown in FIG. 5, and any repetitive detailed description thereof will be omitted.

The first clock signal CKV1 and the third clock signal CKV1B may be charge-shared during a first charge share time tCS1 and a third charge share time tCS3 (shown in FIG. 4). In such an embodiment, the first charge share time tCS1 and the third charge share time tCS3 may be the same as a pulse width of a low level period of the first charge share signal CS1 by the charge share circuit 345 of the first clock delay circuit 220. Similarly, the second clock signal CKV2 and the fourth clock signal CKV2B may be charge-shared during a second charge share time tCS2 and a fourth charge share time tCS4 (shown in FIG. 4) In such an embodiment, the second charge share time tCS2 and the fourth charge share time tCS4 may be the same as a pulse width of a low level period of the second charge share signal CS2 by a charge share circuit of the second clock delay circuit 230.

Referring back to FIGS. 3 and 4, the voltage generator 130 receives one gate pulse signal CPV and outputs the first clock signal CKV1 delayed by the first delay time tDLY1, the second clock signal CKV2 delayed by the second delay time tDLY2, the third clock signal CKV1B delayed by the third delay time tDLY3, and the fourth clock signal CKV2B delayed by the fourth delay time tDLY4.

In an exemplary embodiment, as show in the display device 100 of FIG. 1, only a single gate pulse signal CPV is provided to the voltage generator 130 from the timing controller 120, and thus the number of output terminals of the timing controller 120 and the number of input terminals of the voltage generator 130 may be reduced.

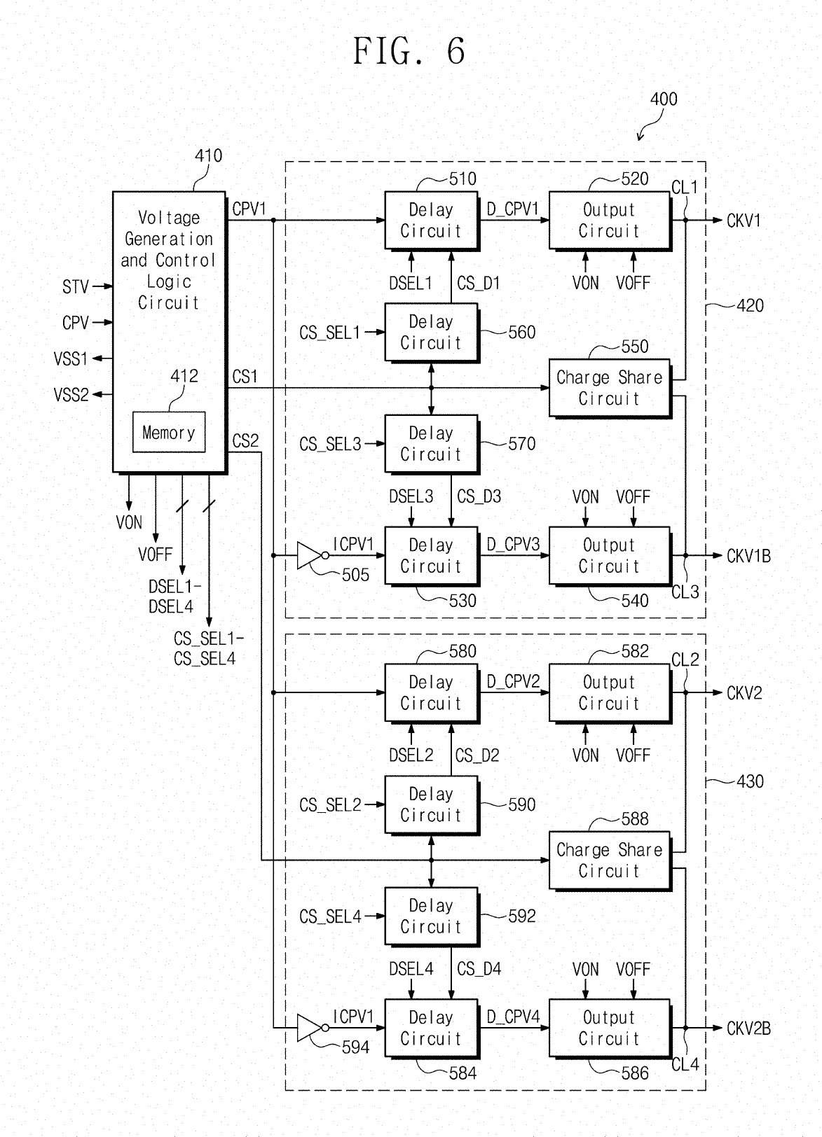

FIG. 6 is a block diagram showing a voltage generator 400 according to an alternative exemplary embodiment of the disclosure.

Referring to FIG. 6, an exemplary embodiment of the voltage generator 400 includes a voltage generation and control logic circuit 410, a first clock delay circuit 420, and a second clock delay circuit 430. The voltage generation and control logic circuit 410 receives the start signal STV and the gate pulse signal CPV from the timing controller 120 (shown in FIG. 1). The voltage generation and control logic circuit 410 generates a first voltage VSS1, a second voltage VSS2, a gate-on voltage VON, and a gate-off voltage VOFF. The voltage generation and control logic circuit 410 may further generate voltages, e.g., a common voltage, a power source voltage, etc., used for the operation of the display device 100. The voltage generation and control logic circuit 410 outputs a reference pulse signal CPV1, first and second charge share signals CS1 and CS2, first, second, third and fourth delay selection signals DSEL1, DSEL2, DSEL3 and DSEL4, and first, second, third and fourth charge share delay signals CS_SEL1, CS_SEL2, CS_SEL3 and CS_SEL4, based on the start signal STV and the gate pulse signal CPV.

The first clock delay circuit 420 delays the reference pulse signal CPV1 during a first delay time tDLY1 in response to the first delay selection signal DSEL1 from the voltage generation and control logic circuit 410 to output the first clock signal CKV1. The first clock delay circuit 420 delays the reference pulse signal CPV1 during a third delay time tDLY3 in response to the third delay selection signal DSEL3 to output the third clock signal CKV1B.

The first clock delay circuit 420 includes first and third delay circuits 510 and 530, first and third output circuits 520 and 540, a charge share circuit 550, first and third charge share delay circuits 560 and 570, and an inverter 505.

The first charge share delay circuit 560 delays the first charge share signal CS1 during a predetermined time in response to the first charge share delay signal CS_SEL1 to output a first delayed charge share signal CS_D1.

The first delay circuit 510 delays the reference pulse signal CPV1 during the first delay time tDLY1 in response to the first delay selection signal DSEL1 and the first delayed charge share signal CS_D1 to output the first delay pulse signal D_CPV1.

The first output circuit 520 includes a level shifter 521, a PMOS transistor 522, and an NMOS transistor 523. The first output circuit 520 converts the first delay pulse signal D_CPV1 to the first clock signal CKV1 swinging between the gate-on voltage VON and the gate-off voltage VOFF and outputs the first clock signal CKV1.

The third charge share delay circuit 570 delays the first charge share signal CS1 during a predetermined time in response to the third charge share delay signal CS_SEL3 to output a third delayed charge share signal CS_D3.

The third delay circuit 530 delays the reference pulse signal CPV1 during the third delay time tDLY3 in response to the third delay selection signal DSEL3 and the third delayed charge share signal CS_D3 to output the third delay pulse signal D_CPV3.

The third output circuit 540 includes a level shifter 541, a PMOS transistor 542, and an NMOS transistor 543. The third output circuit 540 converts the third delay pulse signal D_CPV3 to the third clock signal CKV1B swinging between the gate-on voltage VON and the gate-off voltage VOFF, and outputs the third clock signal CKV1B.

The charge share circuit 550 includes a level shifter 551 and PMOS transistors 552 and 553. In response to the first charge share signal CS1, the charge share circuit 550 electrically connects the first signal line CL1, through which the first clock signal CKV1 is transmitted, and the third signal line CL3, through which the third clock signal CKV1B is transmitted. A circuit configuration and operation of the first clock delay circuit 420 will be described later in greater detail.

The second clock delay circuit 430 includes second and fourth delay circuits 580 and 584, second and fourth output circuits 582 and 586, a charge share circuit 588, second and fourth charge share delay circuits 590 and 592, and an inverter 594.

The second charge share delay circuit 590 delays the second charge share signal CS2 during a predetermined time in response to the second charge share delay signal CS_SEL2 to output a second delayed charge share signal CS_D2.

The second delay circuit 580 delays the reference pulse signal CPV1 during the second delay time tDLY2 in response to the second delay selection signal DSEL2 and the second delayed charge share signal CS_D2 to output the second delay pulse signal D_CPV2.

The second output circuit 582 converts the second delay pulse signal D_CPV2 to the second clock signal CKV2 swinging between the gate-on voltage VON and the gate-off voltage VOFF, and outputs the second clock signal CKV2.

The fourth charge share delay circuit 592 delays the fourth charge share signal CS4 during a predetermined time in response to the fourth charge share delay signal CS_SEL4 to output a fourth delayed charge share signal CS_D4.

The fourth delay circuit 584 delays the reference pulse signal CPV1 during the fourth delay time tDLY4 in response to the fourth delay selection signal DSEL4 and the fourth delayed charge share signal CS_D4 to output the fourth delay pulse signal D_CPV4.

The fourth output circuit 586 converts the fourth delay pulse signal D_CPV4 to the fourth clock signal CKV2B swinging between the gate-on voltage VON and the gate-off voltage VOFF, and outputs the fourth clock signal CKV2B.

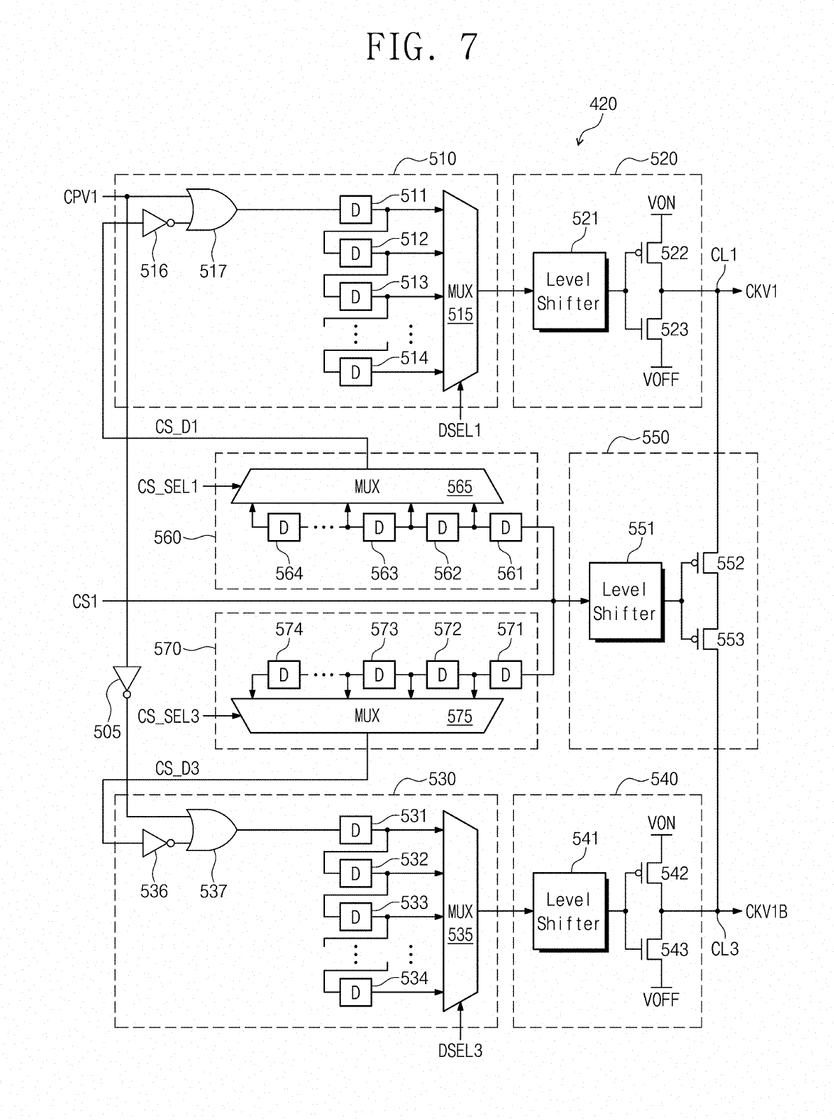

FIG. 7 is a circuit diagram showing an exemplary embodiment of the first clock delay circuit 420 shown in FIG. 6.

Referring to FIG. 7, in an exemplary embodiment, the first charge share delay circuit 560 of the first clock delay circuit 420 includes a plurality of delay units 561 to 564 and a multiplexer 565. A first delay unit 561 of the delay units 561 to 564 receives the first charge share signal CS1. The delay units 561 to 564 are connected to each other in series. The multiplexer 565 receives output signals from the delay units 561 to 564 and outputs a signal output from one of the delay units 561 to 564 as the first delayed charge share signal CS_D1, in response to the first charge share delay signal CS_SEL1.

The first delay circuit 510 includes a plurality of delay units 511 to 514, a multiplexer 515, and logical operation devices 516 and 517. The logical operation device 517 outputs a signal at the low level when the reference pulse signal CPV1 is at the low level and the first delayed charge share signal CS_D1 is at the low level. The logical operation device 516 may include, but not limited to, an inverter, and the logical operation device 517 may include, but not limited to, an OR gate.

The third charge share delay circuit 570 includes a plurality of delay units 571 to 574 and a multiplexer 575. A first delay unit 571 of the delay units 571 to 574 receives the first charge share signal CS1. The delay units 571 to 574 are connected to each other in series. The multiplexer 575 receives output signals from the delay units 571 to 574 and outputs a signal output from one of the delay units 571 to 574 as the third delayed charge share signal CS_D3, in response to the third charge share delay signal CS_SEL3.

The third delay circuit 530 includes a plurality of delay units 531 to 534, a multiplexer 535, logical operation devices 536 and 537. The logical operation device 537 outputs a signal at the low level when the reference pulse signal CPV1 is at the low level and the third delayed charge share signal CS_D3 is at the high level. The logical operation device 537 outputs a signal at the high level when the reference pulse signal CPV1 is not at the low level and the third delayed charge share signal CS_D3 is not at the high level. The logical operation device 536 may include, but not limited to, an inverter, and the logical operation device 537 may include, but not limited to, an OR gate.

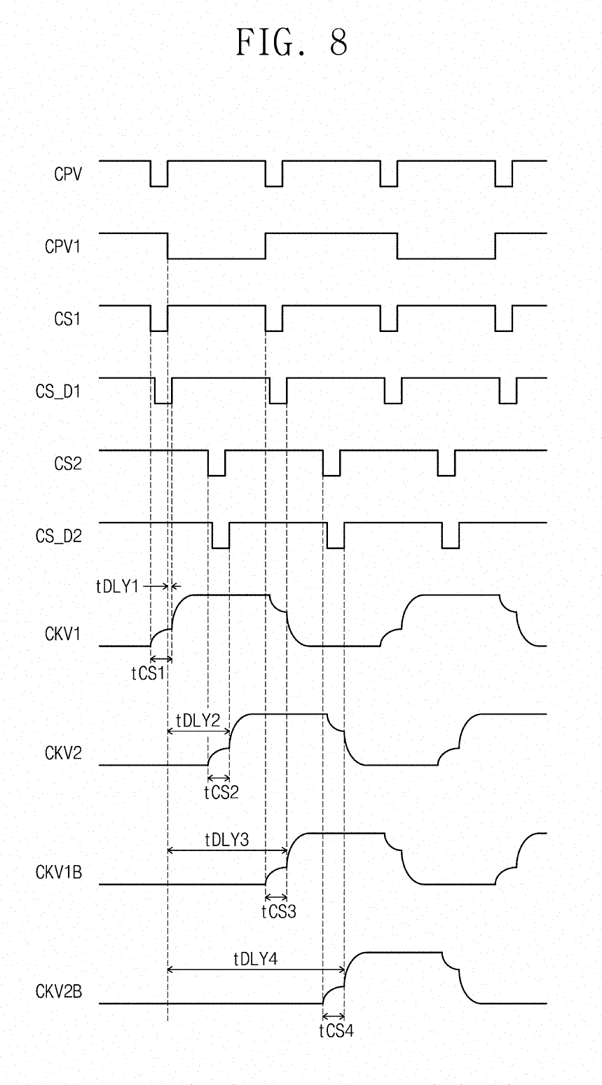

FIG. 8 is a signal timing diagram showing an operation of the voltage generator 400 according to an alternative exemplary embodiment of the disclosure.

Referring to FIGS. 6 and 8, in an exemplary embodiment, a pulse width of the low level period of the first to fourth delayed charge share signals CS_D1 to CS_D4 may be changed depending on the first to fourth charge share delay signals CS_SEL1 to CS_SEL4. Therefore, in such an embodiment, the first to fourth delay times tDLY1 to tDLY4 of the first to fourth clock signals CKV1, CKV2, CKV1B and CKV2B and the pulse width of each of the first to fourth clock signals CKV1, CKV2, CKV1B and CKV2B may be adjusted based on the first to fourth delay selection signals DSEL1 to DSEL4 and the first to fourth delayed charge share signals CS_D1 to CS_D4.

In such an embodiment, the voltage generation and control logic circuit 410 (shown in FIG. 6) may include a memory 412. The memory 412 may store information about the first to fourth delay times tDLY1 to tDLY4 of the first to fourth delay circuits 510, 530, 580, and 584. The voltage generation and control logic circuit 410 may output the first to fourth delay selection signals DSEL1 to DSEL4 based on the information about the first to fourth delay time tDLY1 to tDLY4 stored in the memory 412.

The memory 412 may store information about the first to fourth charge share times tCS1 to tCS4. The voltage generation and control logic circuit 410 may output the first to fourth charge share delay signals CS_SEL1 to CS_SEL4 based on the information about the first to fourth charge share times tCS1 to tCS4 stored in the memory 412.

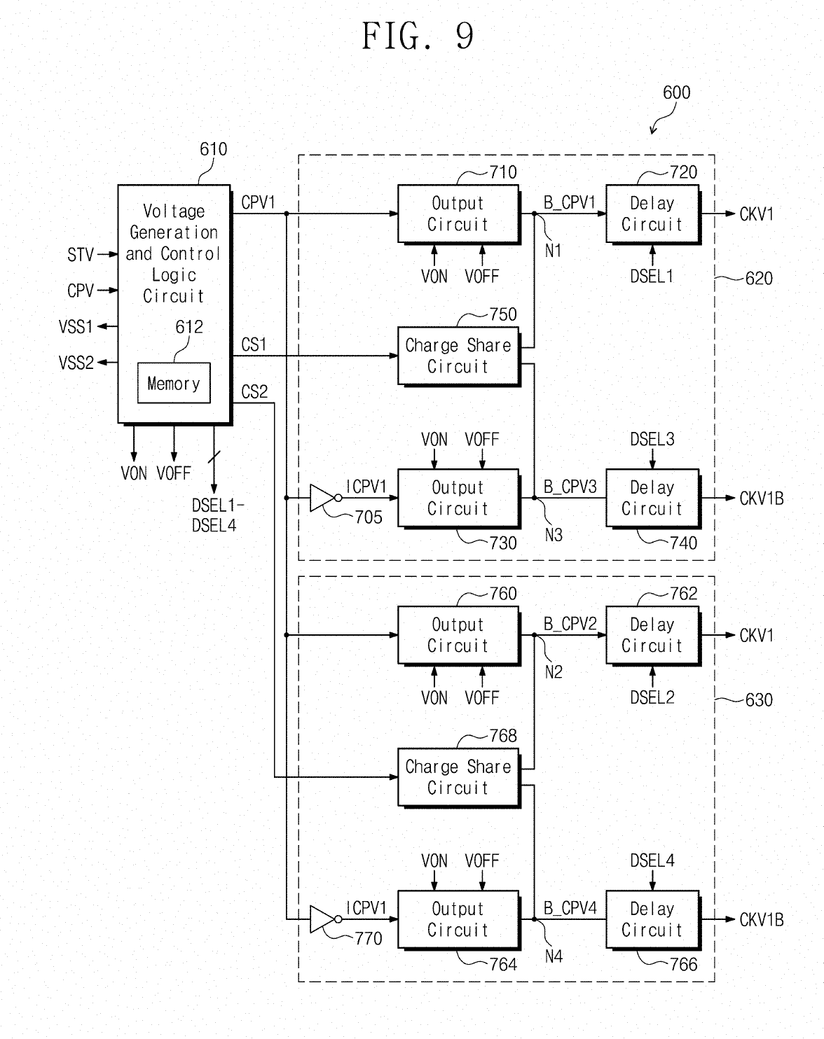

FIG. 9 a block diagram showing a voltage generator 600 according to another alternative exemplary embodiment of the disclosure.

Referring to FIG. 9, an exemplary embodiment of the voltage generator 600 includes a voltage generation and control logic circuit 610, a first clock delay circuit 620, and a second clock delay circuit 630.

In an exemplary embodiment, as shown in FIG. 3, the first delay circuit 310 of the first clock delay circuit 220 is connected to an input terminal of the first output circuit 320. In an alternative exemplary embodiment, as shown in FIG. 9, a first delay circuit 720 of the first clock delay circuit 620 may be connected to an output terminal N1 of a first output circuit 710.

In such an embodiment, a third delay circuit 740 is connected to an output terminal N3 of a third output circuit 730, a second delay circuit 762 is connected to an output terminal N2 of a second output circuit 760, and a fourth delay circuit 766 is connected to an output terminal N4 of a fourth output circuit 764.

In such an embodiment, a charge share circuit 750 electrically connects the output terminal N1 of the first output circuit 710 and the output terminal N3 of the third output circuit 730 in response to the first charge share signal CS1.

In such an embodiment, a charge share circuit 768 electrically connects the output terminal N2 of the second output circuit 760 and the output terminal N4 of the fourth output circuit 764 in response to the second charge share signal CS2.

In such an embodiment, other elements of the voltage generator 600 shown in FIG. 9, e.g., the memory 612 and inverters 705 and 770, are substantially the same as those described above with reference to FIG. 3, and any repetitive detailed description thereof will be omitted.

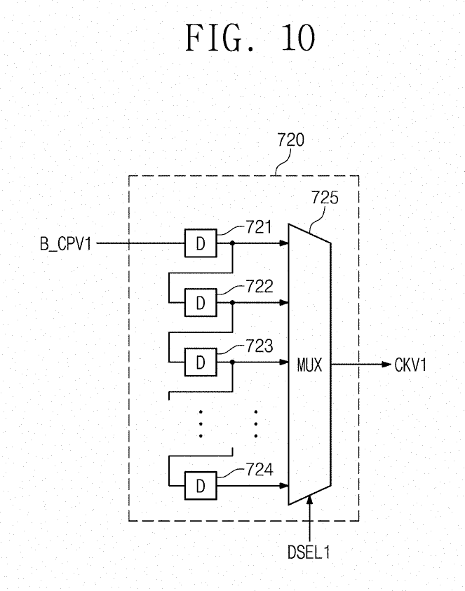

FIG. 10 is a circuit diagram showing an exemplary embodiment of a first delay circuit 720 of a first clock delay circuit shown in FIG. 9.

Referring to FIG. 10, an exemplary embodiment of the first delay circuit 720 includes a plurality of delay units 721 to 724 and a multiplexer 725. A first delay unit 721 receives a first boosting pulse signal B_CPV1 output from the first output circuit 710 (shown in FIG. 9). The delay units 721 to 724 are connected to each other in series. The multiplexer 725 receives output signals from the delay units 721 to 724 and outputs a signal output from one of the delay units 721 to 724 as the first clock signal CKV1 in response to the first delay selection signal DSEL1.

The second, third and fourth delay circuits 762, 740 and 766 shown in FIG. 9 may have a circuit configuration similar to that of the first delay circuit 720 shown in FIG. 10, and any repetitive detailed description thereof will be omitted.

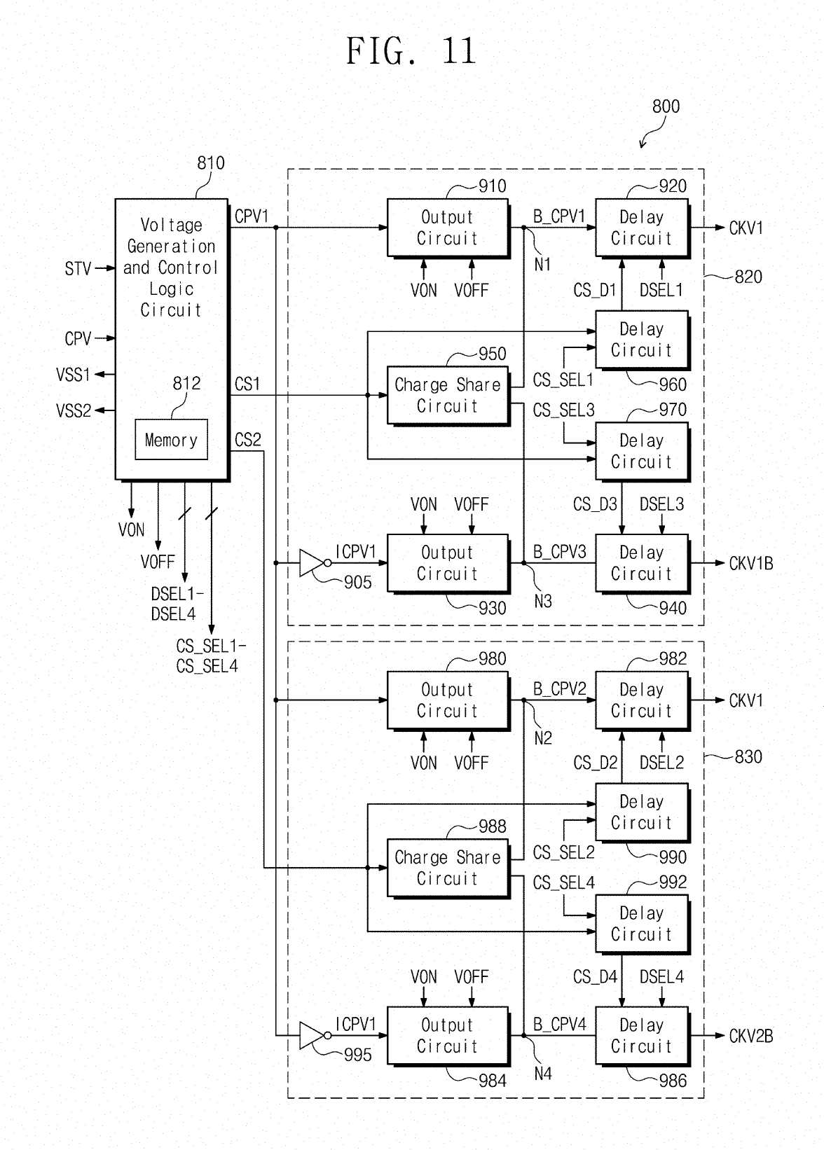

FIG. 11 is a block diagram showing a voltage generator 800 according to another alternative exemplary embodiment of the disclosure.

Referring to FIG. 11, an exemplary embodiment of the voltage generator 800 includes a voltage generation and control logic circuit 810, a first clock delay circuit 820, and a second clock delay circuit 830. The first clock delay circuit 820 has the same configuration as the first clock delay circuit 620 shown in FIG. 9 except that the first and third charge share delay circuits 960 and 970 are further included therein. In such an embodiment, other elements of the voltage generator 600 shown in FIG. 11, e.g., the memory 812, inverters 905 and 995, output circuits 980 and 984, charge share circuits 950 and 988, and delay circuits 982 and 986, are substantially the same as those described above with reference to FIG. 9, and any repetitive detailed description thereof may be omitted.

The first charge share delay circuit 960 delays the first charge share signal CS1 during a predetermined time in response to the first charge share delay signal CS_SEL1 to output the first delayed charge share signal CS_D1.

The first delay circuit 920 delays the first boosting pulse signal B_CPV1 from the first output circuit 910 during the first delay time tDLY1 in response to the first delay selection signal DSEL1 and the first delayed charge share signal CS_D1 to output the first clock signal CKV1.

The third charge share delay circuit 970 delays the first charge share signal CS1 during a predetermined time in response to the third charge share delay signal CS_SEL3 to output the third delayed charge share signal CS_D3.

The third delay circuit 940 delays a third boosting pulse signal B_CPV3 from the third output circuit 930 during the third delay time tDLY3 in response to the third delay selection signal DSEL3 and the third delayed charge share signal CS_D3 to output the third clock signal CKV1B.

The second clock delay circuit 830 shown in FIG. 11 has the same configuration as the second clock delay circuit 630 shown in FIG. 9 except that second and fourth charge share delay circuits 990 and 992 are further included therein. The circuit configuration and operation of the second clock delay circuit 830 are similar to those of the first clock delay circuit 820 except that the output circuits 980 and 984 output boosting pulse signal second and fourth boosting pulse signal B_CPV2 and B_CPV4, and thus, any repetitive detailed description thereof will be omitted.

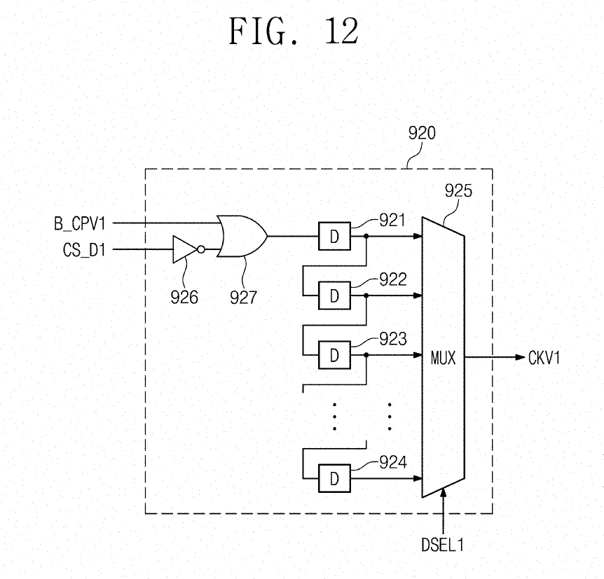

FIG. 12 is a circuit diagram showing an exemplary embodiment of a first delay circuit 920 of a first clock delay circuit shown in FIG. 11.

Referring to FIG. 12, the first delay circuit 920 includes a plurality of delay units 921 to 924, a multiplexer 925, and logical operation devices 926 and 927. The logical operation device 927 outputs a signal at the low level when the boosting pulse signal B_CPV1 is at the low level and the first delayed charge share signal CS_D1 is at the high level. The logical operation device 927 outputs a signal at the high level when the boosting pulse signal B_CPV1 is not at the low level and the first delayed charge share signal CS_D1 is not at the high level. In an exemplary embodiment, the logical operation device 926 may include, but not limited to, an inverter, and the logical operation device 927 may include, but not limited to, an OR gate.

A first delay unit 921 receives an output signal of the logical operation device 927. The delay units 921 to 924 are connected to each other in series. The multiplexer 925 receives output signals from the delay units 921 to 924 and outputs a signal output from one of the delay units 921 to 924 as the first clock signal CKV1, in response to the first delay selection signal DSEL1.

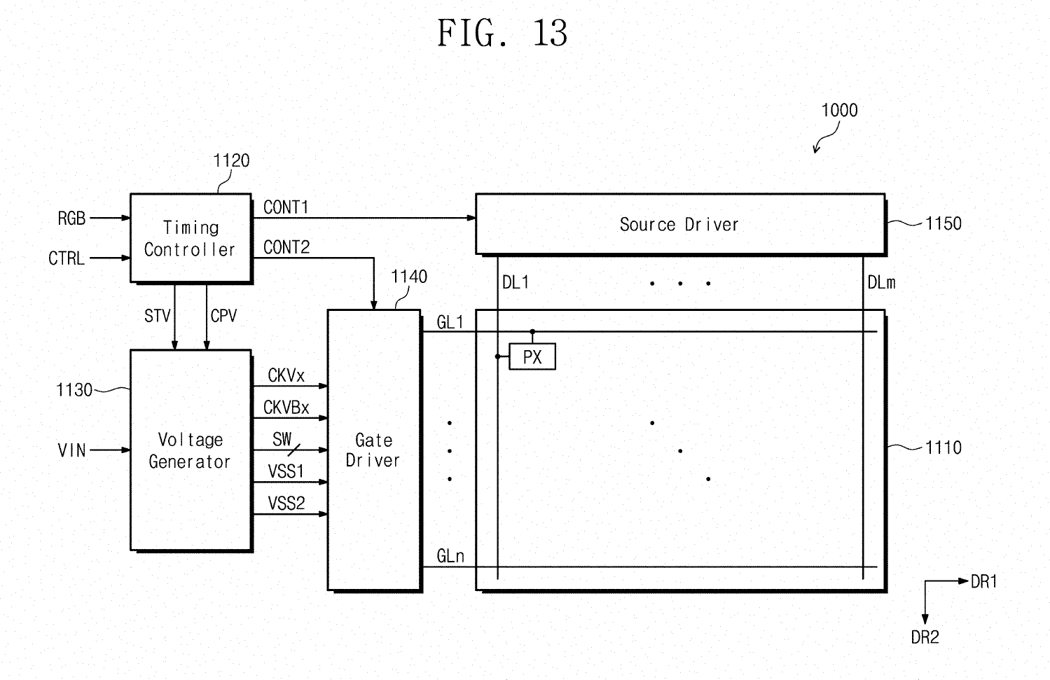

FIG. 13 is a block diagram showing a display device 1000 according to an alternative exemplary embodiment of the disclosure.

Referring to FIG. 13, an exemplary embodiment of the display device 1000 includes a display panel 1110, a timing controller 1120, a voltage generator 1130, a gate driver 1140, and a source driver 1150.

The display panel 1110, the timing controller 1120, and the source driver 1150 shown in FIG. 13 are substantially the same as those of the display panel 110, the timing controller 120 and the source driver 150 shown in FIG. 1, and thus any repetitive detailed description thereof will be omitted.

In an exemplary embodiment, as shown in FIG. 13, the voltage generator 1130 receives the start signal STV and a gate pulse signal CPV from the timing controller 1120. The voltage generator 1130 generates first and second output clock signals CKVx and CKVBx and a switching signal SW based on the start signal STV and the gate pulse signal CPV. The switching signal SW may include a plurality of bits. The voltage generator 1130 applies the switching signal SW to the gate driver 1140. The voltage generator 1130 may receive an input voltage VIN from an external source.

The voltage generator 1130 may further generate a common voltage, a power source voltage and a ground voltage, which are used to drive the display panel 1110, and a first voltage VSS1 and a second voltage VSS2, which are used to drive the gate driver 1140, in addition to the first and second output clock signals CKVx and CKVBx.

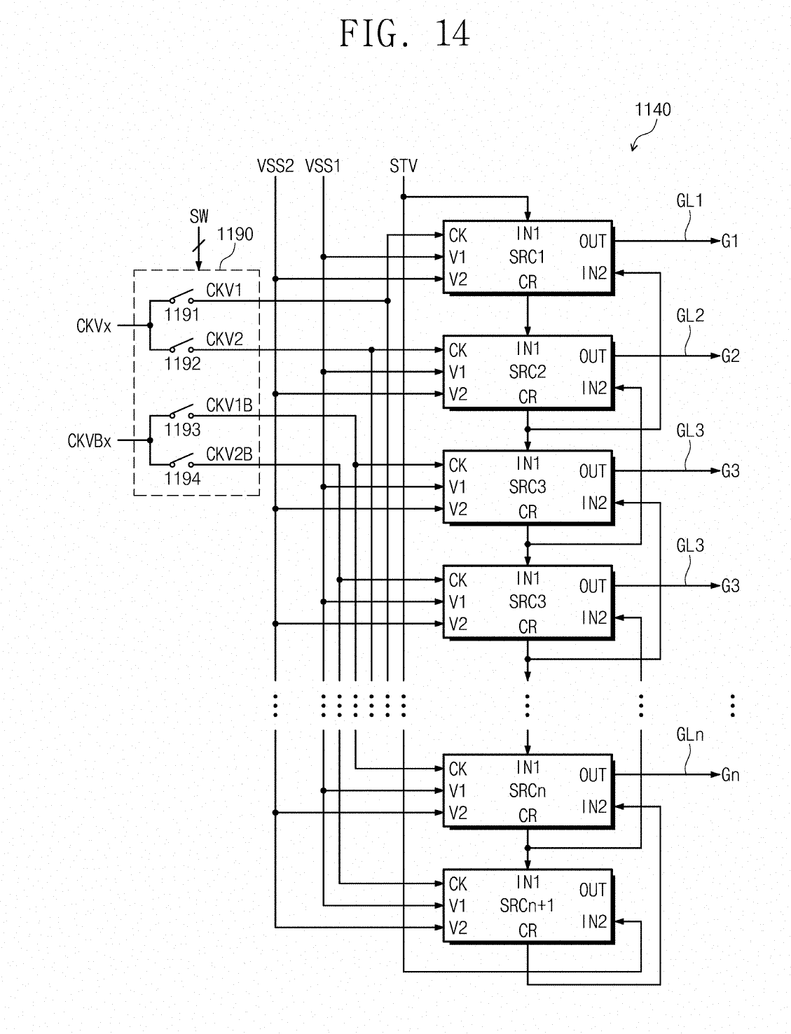

FIG. 14 is a block diagram showing an exemplary embodiment of a gate driver shown in FIG. 13.

Referring to FIG. 14, an exemplary embodiment of the gate driver 1140 includes a switching circuit 1190, a plurality of driving stages SRC1 to SRCn, and a dummy driving stage SRCn+1. The driving stages SRC1 to SRCn and the dummy driving stage SRCn+1 are connected to each other in a cascade matter to allow each driving stage to be driven in response to a carry signal output from a previous driving stage thereof and a carry signal output from a next driving stage thereof.

Each of the driving stages SRC1 to SRCn and the dummy driving stage SRCn+1 receives the first output clock signal CKVx or the second output clock signal CKVBx. The driving stages SRC1 to SRCn and the dummy driving stage SRCn+1 are substantially the same as those of the driving stages SRC1 to SRCn and the dummy driving stage SRCn+1 shown in FIG. 2, and thus, any repetitive detailed description thereof will be omitted.

The switching circuit 1190 includes switching units 1191, 1192, 1193 and 1194. The switching units 1191, 1192, 1193 and 1194 correspond to the first, second, third and fourth clock signals CKV1, CKV2, CKV1B and CKV2B, respectively. The switching units 1191 and 1192 output the first output clock signal CKVx from the voltage generator 1130 (shown in FIG. 13) as the first and second clock signals CKV1 and CKV2, respectively, in response to the switching signal SW. The switching units 1193 and 1194 output the second output clock signal CKVBx from the voltage generator 1130 (shown in FIG. 13) as the third and fourth clock signals CKV1B and CKV2B, respectively, in response to the switching signal SW.

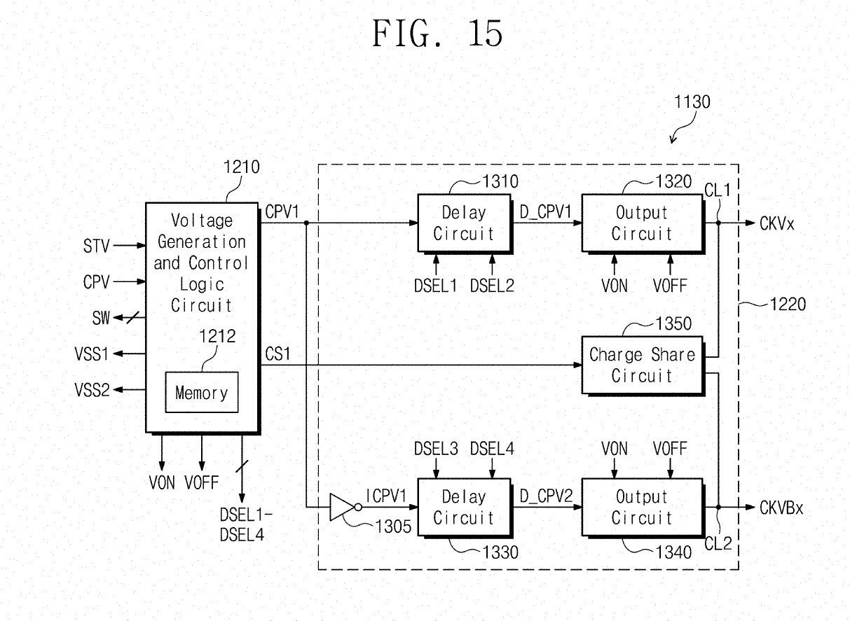

FIG. 15 is a block diagram showing an exemplary embodiment of a voltage generator 1130 shown in FIG. 13.

Referring to FIG. 15, an exemplary embodiment of the voltage generator 1130 includes a voltage generation and control logic circuit 1210 and a clock delay circuit 1220. The voltage generation and control logic circuit 1210 receives the start signal STV and the gate pulse signal CPV from the timing controller 1120 (shown in FIG. 13). The voltage generation and control logic circuit 1210 generates the first voltage VSS1, the second voltage VSS, the gate-on voltage VON and the gate-off voltage VOFF. The voltage generation and control logic circuit 1210 may further generate voltages, e.g., the common voltage and the power source voltage, etc., which are used for the operation of the display device 1000. The voltage generation and control logic circuit 1210 outputs the reference pulse signal CPV1, the switching signal SW, the charge share signal CS1, and the first, second, third and fourth delay selection signals DSEL1, DSEL2, DSEL3 and DSEL4 based on the start signal STV and the gate pulse signal CPV.

The voltage generation and control logic circuit 1210 may include a memory 1212. The memory 1212 may store information about first to fourth delay times tDLY1 to tDLY4. The voltage generation and control logic circuit 1210 may output the first to fourth delay selection signals DSEL1 to DSEL4 based on the information about the first to fourth delay time tDLY1 to tDLY4 stored in the memory 1212. In such an embodiment, the memory 1212 may store information about the switching signal SW. Information about an on-period of each of the switching units 1191 to 1194 shown in FIG. 14 are stored in the memory 1212, and the voltage generation and control logic circuit 1210 may output the switching signal SW based on the information stored in the memory 1212.

In response to the first and second delay selection signals DSEL1 and DSEL2 from the voltage generation and control logic circuit 1210, the clock delay circuit 1220 sequentially outputs the first output clock signal CKVx generated by delaying the reference pulse signal CPV1 during the first delay time tDLY1 and the first output clock signal CKVx generated by delaying the reference pulse signal CPV1 during the second delay time tDLY2. The first output clock signal CKVx generated by delaying the reference pulse signal CPV1 during the first delay time tDLY1 and the first output clock signal CKVx generated by delaying the reference pulse signal CPV1 during the second delay time tDLY2 may partially overlap with each other. In such an embodiment, the first output clock signal CKVx generated by delaying the reference pulse signal CPV1 during the second delay time tDLY2 is output while outputting the first output clock signal CKVx generated by delaying the reference pulse signal CPV1 during the first delay time tDLY1.

In response to the third and fourth delay selection signals DSEL3 and DSEL4, the clock delay circuit 1220 sequentially outputs the second output clock signal CKVBx generated by delaying the reference pulse signal CPV1 during the third delay time tDLY3 and the second output clock signal CKVBx generated by delaying the reference pulse signal CPV1 during the fourth delay time tDLY4. The second output clock signal CKVBx generated by delaying the reference pulse signal CPV1 during the third delay time tDLY3 and the second output clock signal CKVBx generated by delaying the reference pulse signal CPV1 during the fourth delay time tDLY4 may partially overlap with each other. In such an embodiment, the second output clock signal CKVBx generated by delaying the reference pulse signal CPV1 during the fourth delay time tDLY4 is output while outputting the second output clock signal CKVBx generated by delaying the reference pulse signal CPV1 during the third delay time tDLY3.

The clock delay circuit 1220 includes first and second delay circuits 1310 and 1330, first and second output circuits 1320 and 1340, a charge share circuit 1350 and an inverter 1305.

The first delay circuit 1310 sequentially outputs a first delay pulse signal D_CPV1, which is generated by delaying the reference pulse signal CPV1 during the first delay time tDLY1 in response to the first delay selection signal DSEL1, and a first delay pulse signal D_CPV1, which is generated by delaying the reference pulse signal CPV1 during the second delay time tDLY2 in response to the second delay selection signal DSEL2.

The first output circuit 1320 converts the first delay pulse signal D_CPV1 to the first output clock signal CKVx swinging between the gate-on voltage VON and the gate-off voltage VOFF, and outputs the first output clock signal CKVx.

The inverter 1305 inverts the reference pulse signal CPV1, and outputs an inversion reference pulse signal ICPV1.

The second delay circuit 1330 outputs a second delay pulse signal D_CPV2 generated by delaying the inversion reference pulse signal ICPV1 during the third delay time tDLY3 in response to the third delay selection signal DSEL3, and outputs a second delay pulse signal D_CPV2 generated by delaying the inversion reference pulse signal ICPV1 during the fourth delay time tDLY4 in response to the fourth delay selection signal DSEL4.

The second output circuit 1340 converts the second delay pulse signal D_CPV2 to the second output clock signal CKVBx swinging between the gate-on voltage VON and the gate-off voltage VOFF, and outputs the second output clock signal CKVBx.

In response to the charge share signal CS1, the charge share circuit 1350 electrically connects a first signal line CL1, through which the first output clock signal CKVx is transmitted, and a second signal line CL2, through which the second output clock signal CKVBx is transmitted.

Referring to FIGS. 14 and 15, in response to the first delay selection signal DSEL1, the clock delay circuit 1220 sequentially outputs the first output clock signal CKVx generated by delaying the reference pulse signal CPV1 during the first delay time tDLY1 and the first output clock signal CKVx generated by delaying the reference pulse signal CPV1 during the second delay time tDLY2.

In response to the third delay selection signal DSEL3, the clock delay circuit 1220 sequentially outputs the second output clock signal CKVBx, which is generated by delaying the reference pulse signal CPV1 during the third delay time tDLY3, and the second output clock signal CKVBx, which is generated by delaying the reference pulse signal CPV1 during the fourth delay time tDLY4.

The switching circuit 1190 of the gate driver 1140 sequentially turns on the switching units 1191 to 1194 in response to the switching signal SW. In an exemplary embodiment, the switching signal SW has three bits. In one exemplary embodiment, for example, when the switching signal SW is “000”, all the switching units 1191 to 1194 are turned off. In such an embodiment, when the switching signal SW is “001”, the switching unit 1191 is turned on, and the first output clock signal CKVx generated by delaying the reference pulse signal CPV1 during the first delay time tDLY1 is output as the first clock signal CKV1.

In such an embodiment, when the switching signal SW is “010”, the switching unit 1192 is turned on, and the first output clock signal CKVx generated by delaying the reference pulse signal CPV1 during the second delay time tDLY2 is output as the second clock signal CKV2.

In such an embodiment, when the switching signal SW is “011”, the switching unit 1193 is turned on, and the second output clock signal CKVBx generated by delaying the reference pulse signal CPV1 during the third delay time tDLY3 is output as the third clock signal CKV1B.

In such an embodiment, when the switching signal SW is “100”, the switching unit 1194 is turned on, and the second output clock signal CKVBx generated by delaying the reference pulse signal CPV1 during the fourth delay time tDLY4 is output as the fourth clock signal CKV2B.

According to an exemplary embodiment of the display device 1000 shown in FIG. 13, only one gate pulse signal CPV is provided to the voltage generator 1130 from the timing controller 1120, and thus the number of output terminals of the timing controller 1120 and the number of input terminals of the voltage generator 1130 may be reduced.

In such an embodiment, the voltage generator 1130 may provide four clock signals CKV1, CKV2, CKV1B and CKV2B to the gate driver 1140 using two output clock signals CKVx and CKVBx and one switching signal SW. Accordingly, the number of output terminals of the voltage generator 1130 may be minimized.

In exemplary embodiments, as shown in FIGS. 13 to 15, the gate driver 1140 receives the four clock signals, e.g., the first, second, third and fourth clock signals CKV1, CKV2, CKV1B and CKV2B, but not being limited thereto. In an alternative exemplary embodiment, the gate driver 1140 may use eight, twelve, or sixteen clock signals. In such an embodiment, the voltage generator 1130 may provide eight, twelve, or sixteen clock signals to the gate driver 1140 using two output clock signals CKVx and CKVBx and one switching signal SW.

According to an exemplary embodiment, as shown in FIG. 15, the clock delay circuit 1220 of the voltage generator 1130 may have the configuration similar to that of the first clock delay circuit 420 of the voltage generator 400 shown in FIG. 6. In such an embodiment, the clock delay circuit 1220 may control the first to fourth charge share times tCS1 to tCS4 of the first to fourth clock signals CKV1, CKV2, CKV1B and CKV2B.

According to an embodiment, the clock delay circuit 1220 of the voltage generator 1130 shown in FIG. 15 may have the configuration similar to that of the first clock delay circuit 620 of the voltage generator 600 shown in FIG. 9. In such an embodiment, the first delay circuit 1310 of the clock delay circuit 1220 may be connected to the output terminal of the first output circuit 1320. The second delay circuit 1330 may be connected to the output terminal of the second output circuit 1340.

According to an embodiment, the clock delay circuit 1220 of the voltage generator 1130 shown in FIG. 15 may have the configuration similar to that of the first clock delay circuit 820 of the voltage generator 800 shown in FIG. 11. In such an embodiment, the first delay circuit 1310 of the clock delay circuit 1220 may be connected to the output terminal of the first output circuit 1320. The second delay circuit 1330 may be connected to the output terminal of the second output circuit 1340. In such an embodiment, the clock delay circuit 1220 may control the first to fourth charge share times tCS1 to tCS4 of the first to fourth clock signals CKV1, CKV2, CKV1B, and CKV2B.

Although some exemplary embodiments of the invention have been described, it is understood that the invention should not be limited to these exemplary embodiments but various changes and modifications can be made by one ordinary skilled in the art within the spirit and scope of the invention as hereinafter claimed.

What is claimed is:

1. A voltage generator comprising:
a control logic circuit which receives a vertical start signal and a gate pulse signal and outputs a reference pulse signal and delay selection signals;
a first clock delay circuit which delays the reference pulse signal during a first time period in response to a first delay selection signal among the delay selection signals to output a first clock signal; and
a second clock delay circuit which delays the reference pulse signal during a second time period, which is different from the first time period, in response to a second delay selection signal among the delay selection signals to output a second clock signal.

2. The voltage generator of claim 1, wherein
the first clock delay circuit delays the reference pulse signal during a third time period in response to a third delay selection signal among the delay selection signals to output a third clock signal,
the second clock delay circuit delays the reference pulse signal during a fourth time period in response to a fourth delay selection signal among the delay selection signals to output a fourth clock signal,
the first to fourth time periods are in one period of the reference pulse signal and different from each other,
the first clock signal and the third clock signal are substantially complementary to each other, and
the second clock signal and the fourth clock signal are substantially complementary to each other.

3. The voltage generator of claim 2, wherein
the control logic circuit generates a gate-on voltage and a gate-off voltage,
the first clock delay circuit outputs the first and third clock signals, each of which is swinging between the gate-on voltage and the gate-off voltage, and
the second clock delay circuit outputs the second and fourth clock signals, each of which is swinging between the gate-on voltage and the gate-off voltage.

4. The voltage generator of claim 3, wherein the first clock delay circuit comprises:
one delay circuit which outputs one delay pulse signal by delaying the reference pulse signal during the first time period in response to the first delay selection signal;
one output circuit which converts the one delay pulse signal to the first clock signal swinging between the gate-on voltage and the gate-off voltage and outputs the first clock signal;
another delay circuit which outputs another delay pulse signal by delaying the reference pulse signal during the third time period in response to the third delay selection signal; and
another output circuit which converts the another delay pulse signal to the third clock signal swinging between the gate-on voltage and the gate-off voltage and outputs the third clock signal.

5. The voltage generator of claim 4, wherein
the control logic circuit further generates a first charge share signal and a second charge share signal in response to the gate pulse signal, and
the first clock delay circuit further comprises a charge share circuit which electrically connects one signal line, through which the first clock signal is transmitted, to another signal line, through which the third clock signal is transmitted, in response to the first charge share signal.

6. The voltage generator of claim 5, wherein
the control logic circuit further generates charge share delay signals, and
the first clock delay circuit further comprises:
one charge share delay circuit which outputs one delayed charge share signal by delaying the first charge share signal during a predetermined time period in response to one charge share delay signal among the charge share delay signals; and
another charge share delay circuit which outputs another delayed charge share signal by delaying the first charge share signal during a predetermined time period in response to a another charge share delay signal among the charge share delay signals.

7. The voltage generator of claim 6, wherein
the one delay circuit delays the reference pulse signal in response to the first delay selection signal and the one delayed charge share signal to output the one delay pulse signal, and
the another delay circuit delays the reference pulse signal in response to the third delay selection signal and the another delayed charge share signal to output the another delay pulse signal.

8. The voltage generator of claim 3, wherein the first clock delay circuit comprises:
one output circuit which converts the reference pulse signal to one boosting clock signal swinging between the gate-on voltage and the gate-off voltage, and outputs the one boosting clock signal;
one delay circuit which delays the one boosting clock signal during the first time period in response to the first delay selection signal to output the first clock signal;
another output circuit which converts the reference pulse signal to another boosting clock signal swinging between the gate-on voltage and the gate-off voltage and outputs the another boosting clock signal; and
another delay circuit which delays the another boosting clock signal during the third time period in response to the third delay selection signal to output the third clock signal.

9. The voltage generator of claim 8, wherein
the control logic circuit further generates a first charge share signal and a second charge share signal in response to the gate pulse signal, and
the first clock delay circuit further comprises a charge share circuit which electrically connects one signal line, through which the first clock signal is transmitted, to another signal line, through which the third clock signal is transmitted, in response to the first charge share signal.

10. The voltage generator of claim 9, wherein
the control logic circuit further generates charge share delay signals, and
the first clock delay circuit further comprises:
one charge share delay circuit which outputs one delayed charge share signal by delaying the first charge share signal during a predetermined time period in response to one charge share delay signal among the charge share delay signals; and
another charge share delay circuit which outputs another delayed charge share signal by delaying the first charge share signal during a predetermined time period in response to another charge share delay signal among the charge share delay signals.

11. The voltage generator of claim 10, wherein
the one delay circuit delays the one boosting clock signal in response to the first delay selection signal and the one delayed charge share signal to output the first clock signal, and
the another delay circuit delays the another boosting clock signal in response to the third delay selection signal and the another delayed charge share signal to output the third clock signal.

12. The voltage generator of claim 4, wherein the first, second, third and fourth clock signals have different phases from each other within one period of the reference pulse signal.

13. A display device comprising:
a display panel comprising a plurality of gate lines, a plurality of data lines, and a plurality of pixels connected to the gate lines and the data lines;
a gate driver which drives the gate lines;
a data driver which drives the data lines;
a timing controller which outputs a vertical start signal and a gate pulse signal based on a control signal and an image signal from an outside thereof to control the gate driver and the data driver; and
a voltage generator which receives the vertical start signal and the gate pulse signal from the timing controller and outputs a driving voltage, a first clock signal and a second clock signal,
wherein the voltage generator comprises:
a control logic circuit which receives the vertical start signal and the gate pulse signal and outputs a reference pulse signal and delay selection signals;
a first clock delay circuit which delays the reference pulse signal during a first time period in response to a first delay selection signal among the delay selection signals to output the first clock signal; and
a second clock delay circuit which delays the reference pulse signal during a second time period, which is different from the first time period, in response to a second delay selection signal among the delay selection signals to output the second clock signal.

14. The display device of claim 13, wherein
the first clock delay circuit delays the reference pulse signal during a third time period in response to a third delay selection signal among the delay selection signals to output a third clock signal,
the second clock delay circuit delays the reference pulse signal during a fourth time period in response to a fourth delay selection signal among the delay selection signals to output a fourth clock signal,
the first clock signal and the third clock signal are substantially complementary to each other, and
the second clock signal and the fourth clock signal are substantially complementary to each other.

15. The display device of claim 14, wherein
the control logic circuit generates a gate-on voltage and a gate-off voltage,
the first clock delay circuit outputs the first and third clock signals, each of which is swinging between the gate-on voltage and the gate-off voltage, and
the second clock delay circuit outputs the second and fourth clock signals, each of which is swinging between the gate-on voltage and the gate-off voltage.

16. A display device comprising:
a display panel comprising a plurality of gate lines, a plurality of data lines, and a plurality of pixels connected to the gate lines the data lines;
a gate driver which drives the gate lines;
a data driver which drives the data lines;
a timing controller which outputs a vertical start signal and a gate pulse signal based on a control signal and an image signal from an outside thereof to control the gate driver and the data driver; and
a voltage generator which receives the vertical start signal and the gate pulse signal from the timing controller and outputs a driving voltage, a switching signal, a first output clock signal and a second output clock signal,
wherein the voltage generator comprises:
a control logic circuit which receives the vertical start signal and the gate pulse signal to output a reference pulse signal, the switching signal, and first, second, third and fourth delay selection signals; and
a clock delay circuit which sequentially outputs the first output clock signal and sequentially outputs the second output clock signal, wherein the first output clock signal is generated by delaying the reference pulse signal during a first time period and generated by delaying the reference pulse signal during a second time period in response to the first and second delay selection signals, and the second output clock signal is generated by delaying the reference pulse signal during a third time period and generated by delaying the reference pulse signal during a fourth time period in response to the third and fourth delay selection signals,
wherein the gate driver drives the gate lines based on the switching signal, the first output clock signal and the second output clock signal.

17. The display device of claim 16, wherein the gate driver comprises:
a switching circuit which sequentially outputs the first output clock signal as first and second clock signals in response to the switching signal, and sequentially outputs the second output clock signal as third and fourth clock signals in response to the switching signal; and
a plurality of stages which drives the gate lines in synchronization with the first, second, third and fourth clock signals.

18. The display device of claim 17, wherein the switching circuit comprises:
a first switching unit which outputs the first output clock signal as the first clock signal in response to the switching signal;
a second switching unit which outputs the first output clock signal as the second clock signal in response to the switching signal;
a third switching unit which outputs the second output clock signal as the third clock signal in response to the switching signal; and
a fourth switching unit which outputs the second output clock signal as the fourth clock signal in response to the switching signal.

19. The display device of claim 16, wherein
the control logic circuit generates a gate-on voltage and a gate-off voltage, and
the clock delay circuit comprises:
a first delay circuit which sequentially outputs a first delayed pulse signal, wherein the first delayed pulse signal is generated by delaying the reference pulse signal during the first time period and generated by delaying the reference pulse signal during the second time period in response to the first and second delay selection signals;
a first output circuit which converts the first delayed pulse signal to the first output clock signal swinging between the gate-on voltage and the gate-off voltage and outputs the first output clock signal;
a second delay circuit which sequentially outputs a second delayed pulse signal, wherein second delayed pulse signal is generated by delaying the reference pulse signal during the third time period and generated by delaying the reference pulse signal during the fourth time period in response to the third and fourth delay selection signals; and
a second output circuit which converts the second delayed pulse signal to the second output clock signal swinging between the gate-on voltage and the gate-off voltage and outputs the second output clock signal.

20. The display device of claim 19, wherein
the control logic circuit further generates a charge share signal in response to the gate pulse signal, and
the clock delay circuit further comprises a charge share circuit which electrically connects one signal line, through which the first output clock signal is transmitted, and another signal line. through which the second output clock signal is transmitted. in response to the charge share signal.
